(19) United States
(12) Patent Application Publication
(10) Pub. No.: US 2014/0083847 A1
(43) Pub. Date: Mar. 27, 2014

(54) Fe-Pt-C Based Sputtering Target

(71) Applicant: Atsushi Sato, Ibaraki (JP)

(72) Inventor: Atsushi Sato, Ibaraki (JP)

(73) Assignee: JX Nippon Mining & Metals Corporation, Tokyo (JP)

(21) Appl. No.: 14/118,792

(22) PCT Filed: Jul. 20, 2012
(86) PCT No.: PCT/JP2012/068411

§ 371 Date: Nov. 19, 2013

(30) Foreign Application Priority Data
Sep. 26, 2011 (JP) 2011-209493

(51) Int. Cl. C23C 14/16

(52) U.S. Cl. CPC C23C 14/165
USPC 204/298.13; 419/31

(57) ABSTRACT

Provided is a sintered sputtering target having a composition by atomic ratio represented by the formula: (Fe_{100-X}—Pt_{X})_{100-A}C_{A} (wherein A and X satisfy 20≦A≦50 and 35≦X≦55, respectively), wherein C particles are finely dispersed in a matrix alloy, and an oxygen content is 300 wt ppm or less. An object of the present invention is to provide an Fe—Pt based sputtering target having finely dispersed C particles and a low oxygen content, which allows manufacture of a granular structure magnetic thin film having excellent corrosion resistance, and further allows facilitation of ordering the L1₀ structure.

### TECHNICAL FILED

The present invention relates to a sputtering target used for depositing a granular magnetic thin film in a magnetic recording medium. The present invention also relates to an Fe—Pt based sputtering target wherein C particles are dispersed in a matrix alloy.

### BACKGROUND

In the field of the magnetic recording represented by hard disk drives, a material based on a ferromagnetic metal Co, Fe or Ni is used as a material for a magnetic thin film in a magnetic recording medium. For example, a Co—Cr—Pt based ferromagnetic alloy having Co as a main component has been used for a magnetic thin film of a hard disk in which the in-plane magnetic recording system is used. Further, a composite material comprising a Co—Cr—Pt based ferromagnetic alloy having Co as a main component and a non-magnetic material is often used for a magnetic thin film of a hard disk in which the recently commercialized perpendicular magnetic recording method is used. In many cases, the above magnetic thin film is manufactured by sputtering a sputtering target comprising the above materials as components using a DC magnetron sputtering device in view of high productivity.

Recording density of a hard disk is rapidly increasing every year, and will likely become more than 1 Tbit/in² in the future. However, in a case where recording density reaches 1 Tbit/in², the size of a recording bit is smaller than 10 nm. In that case, superparamagnetism due to thermal fluctuation will likely pose a problem, and materials for magnetic recording media currently used, for example, a material in which magnetocrystalline anisotropy is enhanced by adding Pt to a Co—Cr based alloy will not likely to be sufficient. This is because a particle having a size of 10 nm or less and stably showing a ferromagnetic behavior is required to have higher magnetocrystalline anisotropy.

For these reasons, an FePt ordered alloy having the L1₀ structure attracts attention as a material for ultrahigh density recording media. An FePt having the L1₀ structure, which has high magnetocrystalline anisotropy as well as excellent corrosion resistance and oxidation resistance, is expected to be a suitable material for use in magnetic recording media.

In a case where the FePt is used as a material for ultrahigh density recording media, a technology needs to be developed in which FePt magnetic particles having the L1₀ structure are dispersed as high density as possible in a magnetically isolated fashion with the C axis aligned in a perpendicular direction against the substrate.

For the above reasons, a granular structure magnetic thin film in which FePt magnetic particles having the L1₀ structure are magnetically isolated with a non-magnetic material such as oxides and carbon has been proposed for a magnetic recording medium of a next generation hard disk in which the heat assisted magnetic recording method is used. Specifically, the granular structure magnetic thin film has a structure in which the grain boundary of magnetic particles is filled with a non-magnetic substance. Magnetic recording media having a granular structure magnetic thin film and related technologies thereof have been proposed (Patent Literatures 1 to 5).

For the granular structure magnetic thin film comprising an FePt having the L1₀ structure, a magnetic thin film comprising 10 to 50% of C by volume ratio as a non-magnetic substance particularly attracts attention in view of high magnetic properties. It is known that such a granular structure magnetic thin film is manufactured by co-sputtering an Fe target, a Pt target and a C target, or by co-sputtering an Fe—Pt alloy target and a C target. In order to co-sputter these sputtering targets, however, an expensive co-sputtering device is required.

Thus, manufacturers of hard disk media, who pursue inexpensive large scale production, are in the process of developing a granular structure magnetic thin film having a good property obtainable by sputtering a composite sputtering target comprising an Fe—Pt alloy and C using a magnetron sputtering device. Here, in general, when sputtering a composite sputtering target comprising an alloy and a non-magnetic material using a sputtering device, a problem may arise that the non-magnetic material is inadvertently released during sputtering to cause the development of particles i.e. dust adhered on a substrate.

In order to solve the above problem, finely dispersing a non-magnetic material in a matrix alloy and densifying a sputtering target to improve adherence between the non-magnetic material and the matrix alloy are effective. In general, a sputtering target in which a non-magnetic material is dispersed in a matrix alloy is manufactured by a powder sintering method. In this case, the driving force of sintering greatly depends on the specific surface area of the metal powder before sintering. In other words, a metal powder with a smaller particle diameter will produce a much highly densified sintered compact. Further, in order to finely disperse a non-magnetic material in a matrix alloy, a sintering powder needs to be prepared in which a non-magnetic material powder having a small particle diameter is highly dispersed in a metal powder having a similar particle diameter.

However, when a particle diameter of the sintering powder is small, an amount of oxygen in the powder increases due to the effect of surface oxidation of the metal powder. Further, sintering such a powder having a high oxygen content also tends to increase an amount of oxygen in a sintered compact. In a case where a granular structure magnetic film is manufactured by sputtering an Fe—Pt—C based sputtering target having a high oxygen content, corrosion resistance may decrease. This may be because oxygen is likely incorporated into FePt magnetic particles to form an oxide of Fe. Moreover, in a case where an oxide of Fe is present in a sputtering film, when attempting ordering of the Fe—Pt phase by annealing, the ordering may be difficult.

Patent Literature 6 describes a Fe—Pt—C target having an oxygen content of 500 wt ppm or less, but fails to describe specific measures to reduce the amount of oxygen. When trying to finely disperse C particles with a particle diameter in the order of micrometers or smaller in a matrix alloy, a sintering powder also needs to be sized to at least the order of micrometers or smaller. In this case, even though the manufacturing method described in Example of Patent Literature 6 can reduce an oxygen content in a sputtering target to 500 wt ppm or less, it is difficult to reduce the oxygen content in the sputtering target further down to about 300 wt ppm or less.

Patent Literature 7 suggests a method of preparing an alloy film such as an Fe—Pt alloy in which the amount of a residual gas content is reduced by reducing the amount of a gas content in a target used for sputter deposition. However, with regard to measures of reducing a gas content in a target, no specific measures are described therein except that an Fe ingot with low impurities and a low gas content is used. It also describes that C is not preferred because an ordering temperature of a magnetic alloy film increases, resulting in a decreased magnetic property.

### CITATION LIST

### Patent Literature

Patent Literature 1: Japanese Patent Laid-Open No. 2000-306228

Patent Literature 2: Japanese Patent Laid-Open No. 2000-311329

Patent Literature 3: Japanese Patent Laid-Open No. 2008-59733

Patent Literature 4: Japanese Patent Laid-Open No. 2008-169464

Patent Literature 5: Japanese Patent Laid-Open No. 2004-152471

Patent Literature 6: W02012/086335

Patent Literature 7: Japanese Patent Laid-Open No. 2003-313659

### SUMMARY OF THE INVENTION

### Technical Problem

An object of the present invention is to provide a Fe-Pt based sputtering target having finely dispersed C particles and a low oxygen content, which allows manufacture of a granular structure magnetic thin film having excellent corrosion resistance, and further allows facilitation of ordering the L1₀ structure.

### Solution to Problem

After conducting intensive studies in order to achieve the above object, the present inventors found that oxidation of a sintering powder can be suppressed by heat-treating a metal powder along with a C powder, and that an Fe—Pt—C based sputtering target manufactured using the sintering powder can have an oxygen content of 300 wt ppm or less.

Based on these findings, the present invention provides:

1) A sintered sputtering target having a composition by atomic ratio represented by the formula: (Fe_{100-X}-Pt_{X})_{100-A}C_{A} (wherein A and X satisfy 20≦A≦50 and 35≦X≦55, respectively), wherein C particles are finely dispersed in a matrix alloy, and an oxygen content is 300 wt ppm or less.
2) A sintered sputtering target having a composition by atomic ratio represented by the formula: (Fe_{100-X-Y}—Pt_{X}-M_{Y})_{100-A}C_{A} (wherein M is a metal element other than Fe and Pt, and A, X and Y satisfy 20≦A≦50, 35≦X≦55 and 0.5≦Y≦15, respectively), wherein C particles are finely dispersed in a matrix alloy, and an oxygen content is 300 wt ppm or less.
3) The sputtering target according to 2), wherein the metal element M is either Cu or Ag.
4) A method of manufacturing a sputtering target, the method comprising: mixing a metal powder and a C powder; heat-treating the mixed powder at temperature of 750° C. or more and 1100° C. or less under an inert gas atmosphere or a vacuum atmosphere; and performing sintering using the resulting powder as a part of a raw powder.
5) The method of manufacturing a sputtering target according to 4), the method comprising: filling a mold with the heat-treated powder; and then molding and sintering by uniaxial pressing at a pressure of 20 to 50 MPa; and then molding and sintering by hot isostatic pressing at a pressure of 100 to 200 MPa.

### Effect of Invention

The Fe—Pt based sputtering target of the present invention having finely dispersed C particles and a low oxygen content has the following effects: it allows manufacture of a granular structure magnetic thin film having excellent corrosion resistance, and further allows facilitation of ordering the L1₀ structure.

### BRIEF DESCRIPTION OF THE DRAWINGS

FIG. 1 shows an image of a structure of the polished surface of the sintered compact according to Example 1 of the present invention observed under an optical microscope.

### DETAILED DESCRIPTION OF THE INVENTION

The Fe—Pt—C based sputtering target of the present invention has a composition by atomic ratio represented by the formula: (Fe_{100-X}—Pt_{X})_{100-A}C_{A} (wherein A and X satisfy 20≦A≦50 and 35≦X≦55, respectively), C particles finely dispersed in a matrix alloy uniformly and an oxygen content of 300 wt ppm or less.

According to the present invention, the content of C particles is preferably 20 or more and 50 or less by atomic ratio in the sputtering target composition. In a case where the content of C particles in the target composition is less than 20 by atomic ratio, a granular structure magnetic thin film having a good property may not be obtained; while in the case of more than 50 by atomic ratio, C particles may aggregate, resulting in increased particle generation.

Further, according to the present invention, the content of Pt is preferably 35 or more and 55 or less by atomic ratio in the Fe—Pt alloy composition. This is because in a case where the Pt content in an Fe—Pt alloy is less than 35 by atomic ratio, it gives a composition range where an Fe—Pt with the L1₀ structure having high magnetocrystalline anisotropy will not be developed, and in a case where the Pt content in the Fe—Pt alloy is more than 55 by atomic ratio, it gives a composition range where the Fe—Pt with the L1₀ structure also will not be developed.

Further, according to the present invention, a metal element other than Fe and Pt can be added. That is, a sputtering target having a composition by atomic ratio represented by the formula: (Fe_{100-X-Y}—Pt_{X}—M_{Y})_{100-A}C_{A} (wherein M is a metal element other than Fe and Pt, and A, X and Y satisfy 20≦A≦50, 35≦X≦55 and 0.5≦Y≦15, respectively), C particles finely dispersed in a matrix alloy, and an oxygen content of 300 wt ppm or less can be provided.

By adding a metal element other than Fe and Pt, a heat treatment temperature at which a deposited granular structure magnetic thin film forms the L1₀ structure can be lowered, and further, saturation magnetization and magnetic coercive force of the magnetic thin film can be adjusted to a value optimal for magnetic recording media. Thus, the addition is effective.

According to the present invention, in a case where a metal element other than Fe and Pt is added as described above, the content of Pt also is preferably 35 or more and 55 or less by atomic ratio in the Fe—Pt—M alloy composition. This is because the Pt content of less than 35 by atomic ratio or more than 55 by atomic ratio in the Fe—Pt—M alloy gives a composition range where an Fe—Pt having the L1₀ structure will not be developed.

Further, the content of the metal element M is preferably 0.5 or more and 15 or less by atomic ratio in the Fe—Pt—M alloy composition. This is because the effects described above may not be obtained when the content of the added metal element in the Fe—Pt—M alloy is less than 0.5 by atomic ratio while sufficient magnetocrystalline anisotropy may not be obtained when the content is more than 15 by atomic ratio.

According to the present invention, Cu and Ag are particularly effective as a metal element to be added. These elements are effective because they show an effect that a heat treatment temperature at which a deposited granular structure magnetic thin film forms the L1₀ structure can be significantly lowered.

Further, the sputtering target of the present invention preferably comprises any one or more of the following non-magnetic materials: borides, carbides, nitrides and carbon nitrides. Since these non-magnetic materials can be deposited at the grain boundary of Fe-Pt magnetic particles to magnetically shield the magnetic particles from each other in a similar fashion as C (carbon), good magnetic properties can be obtained.

Moreover, the sputtering target of the present invention can be manufactured by heat-treating a mixed powder of a metal powder and a C powder at 750° C. or more and 1100° C. or less under an inert gas atmosphere or a vacuum atmosphere, and performing sintering using the resulting powder as a part of the raw powder.

In the present invention, the heat treatment temperature is important. When a mixed powder of a metal powder and a C powder is heat-treated at a temperature of 750° C. or higher, a certain amount of C is solid dissolved in the metal, and C which no longer can be solid dissolved will be deposited to cover the surface of the metal powder in the cooling step. Surface oxidation of the metal powder is expected to be suppressed by this. On the other hand, a temperature of 750° C. or lower is not preferred because the reaction of a metal powder and a C powder may not sufficiently progress. Further, at a temperature of 1100° C. or higher, a metal powder may undergo grain growth.

Further, according to the sputtering target of the present invention, a sintered compact can be manufactured by filling a graphite mold with the heat-treated powder; performing molding and sintering by uniaxial pressing at a pressure of 20 to 50 MPa; and then further performing molding and sintering by hot isostatic pressing at a pressure of 100 to 200 MPa.

In order to suppress dust development generated from a target upon sputtering the target, it is important to prepare a target with improved density. According to the present invention, a denser sintered compact can be manufactured by further performing hot isostatic pressing on the sintered compact molded and sintered with a uniaxial pressing-sintering device. In order to increase the density of a target, pressurizing force is desirably set as high as possible within the pressure range which the device can handle.

The sputtering target of the present invention can be manufactured by the powder sintering method. Upon manufacturing, each raw powder of an Fe powder, a Pt powder, a C powder, and an additive metal element powder, if needed, is prepared. These powders to be used desirably have a particle diameter of 0.1 μm or more and 10 μm or less. Too small a particle diameter of a raw powder makes it difficult to be homogeneously mixed with each other due to aggregation of the powder. Desirably, the particle diameter is 0.5 μm or more.

On the other hand, too large a particle diameter of a raw powder makes it difficult to be finely dispersing C particles in an alloy. Hence, desirably a raw powder having a particle diameter of 10 μm or less is used.

Further, an alloy powder may be used as a raw powder. In a case where an alloy powder is used, an alloy powder having a particle diameter of 0.5 μm or more and 10 μm or less is also desirably used.

Then, the above powders are weighed to give a desired composition, and ground and mixed using a known approach such as ball milling. Next, the powder mixed with a ball mill is heat-treated under an inert gas atmosphere or a vacuum atmosphere. The heat treatment is desirably performed under the conditions in which the temperature is maintained at 750° C. or more and 1100° C. or less for 2 hours or more. Thereby, an amount of oxygen in the raw powders can be significantly reduced.

The heat-treated powder as described above is crushed and ground using a known method such as ball milling to complete a mixed powder for sintering. At this time, a non-heat-treated powder may be mixed. For example, a non-heat-treated C powder is further added to (a part of) the heat-treated mixed powder of an Fe powder, a Pt powder and a C powder.

Then, a carbon mold is filled with the resulting powder to perform molding and sintering by hot press. In addition to hot press, the plasma discharge sintering method may be used. The temperature during sintering is often maintained in the temperature range between 850° C. and 1400° C., depending on a composition of the sputtering target. Further, pressurizing force is preferably set to 20 MPa or more, more preferably 20 to 50 MPa.

Then, the sintered compact removed from the hot press is subjected to hot isostatic press. Hot isostatic press is effective for improving the density of a sintered compact. The temperature during hot isostatic pressing is often maintained in the temperature range between 850° C. and 1400° C., depending on a composition of the sintered compact. Further, pressurizing force is set to 100 MPa or more, preferably 100 to 200 MPa. By processing the thus-obtained sintered compact into a desired shape with a lathe, the sputtering target of the present invention can be manufactured.

As described above, an Fe—Pt—C based sputtering target can be manufactured in which C particles are uniformly and finely dispersed in a matrix alloy, and the oxygen content of the sputtering target is 300 wt ppm or less.

### EXAMPLES

The present invention will be described based on Examples and

Comparative Examples in the followings. Note that Examples are merely illustrative and the present invention shall in no way be limited thereby. That is, the present invention is limited only by the claims, and shall encompass various modifications other than those included in Examples of the present invention.

### Example 1

An Fe powder having an average particle diameter of 3 μm, a Pt powder having an average particle diameter of 3 μm and a C powder having an average particle diameter of 1 μm were prepared as raw powders. For the C powder, a commercially available amorphous carbon was used. These powders were weighed to give a total weight of 2600 g and the following atomic ratio.

Atomic ratio: (Fe₅₀—Pt₅O₆₀—C₄₀

Next, the weighed powders were transferred and sealed in a 10 L ball mill pot along with zirconia balls as grinding media, and rotated for 4 hours for mixing and grinding. Then the mixed powder was removed from the ball mill to perform heat treatment.

The conditions of the heat treatment were as follows: Ar atmosphere (atmospheric pressure), the rate of temperature increase: 300° C./hour, holding temperature: 900° C. and holding time: 2 hours. The powder was removed from the heat-treating furnace after naturally cooled, and transferred and sealed in a 10 L ball mill pot along with zirconia balls as grinding media, and rotated for 4 hours for crushing and grinding.

A carbon mold was then filled with the crushed and ground powder for hot pressing.

The conditions of the hot pressing were as follows: vacuum atmosphere, the rate of temperature increase: 300° C./hour, holding temperature: 1200° C. and holding time: 2 hours, and pressure was applied at 30 MPa from the beginning of temperature increase through to the end of holding. After holding, it was kept in the chamber to allow natural cooling.

Next, the sintered compact removed from the mold for the hot pressing was subjected to hot isostatic pressing. The conditions of the hot isostatic pressing were as follows: the rate of temperature increase: 300° C./hour, holding temperature: 1350° C. and holding time: 2 hours, and the gas pressure of Ar gas was gradually increased from the beginning of temperature increase, and pressure was applied at 150 MPa during holding at 1350° C. After holding, it was kept in the furnace to allow natural cooling.

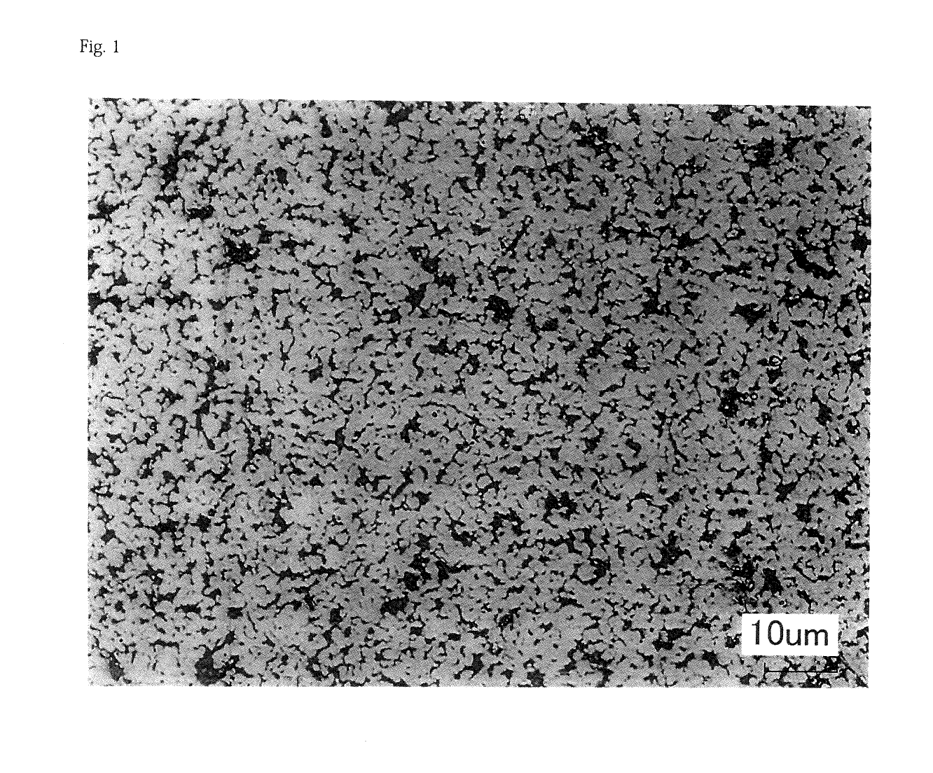

The sintered compact manufactured in this way was subject to cutting work with a lathe to obtain a sputtering target. At the same time, a sample for oxygen analysis was cut out from the sintered compact, and the oxygen content was measured to be 190 wt ppm. Further, the sintered compact was polished, and the structure was observed with an optical microscope. As shown in FIG. 1, a structure was observed that C particles which are blackish portions in the structure image are finely dispersed in the Fe—Pt alloy which is white in the structure image.

### Comparative Example 1

An Fe powder having an average particle diameter of 3 μm, a Pt powder having an average particle diameter of 3 μm and a C powder having an average particle diameter of 1 μm were prepared as raw powders. For the C powder, a commercially available amorphous carbon was used.

These powders were weighed to give a total weight of 2600 g and the following atomic ratio.

Atomic ratio: (Fe₅₀—Pt₅₀)₆₀—C₄₀

Next, the weighed powders were transferred and sealed in a 10 L ball mill pot along with zirconia balls as grinding media, and rotated for 4 hours for mixing and grinding. A carbon mold was then filled with the mixed powder removed from the ball mill for hot pressing.

The conditions of the hot pressing were as follows: vacuum atmosphere, the rate of temperature increase: 300° C./hour, holding temperature: 1200° C. and holding time: 2 hours, and pressure was applied at 30 MPa from the beginning of temperature increase through to the end of holding. After holding, it was kept in the chamber to allow natural cooling.

Next, the sintered compact removed from the mold for the hot pressing was subjected to hot isostatic pressing. The conditions of the hot isostatic pressing were as follows: the rate of temperature increase: 300° C./hour, holding temperature: 1350° C. and holding time: 2 hours, and the gas pressure of Ar gas was gradually increased from the beginning of temperature increase and pressure was applied at 150 MPa during holding at 1350° C. After holding, it was kept in the furnace to allow natural cooling.

The sintered compact manufactured in this way was subject to cutting work with a lathe to obtain a sputtering target. At the same time, a sample for oxygen analysis was cut out from the sintered compact, and the oxygen content was measured to be 560 wt ppm. Further, the sintered compact was polished to observe the cross section, and a structure was observed in which C particles are finely dispersed in the Fe—Pt alloy.

### Example 2

An Fe powder having an average particle diameter of 3 μm, a Pt powder having an average particle diameter of 3 μm, a Cu powder having an average particle diameter of 3 μm and a C powder having an average particle diameter of 1 μm were prepared as raw powders. For the C powder, a commercially available amorphous carbon was used.

These powders were weighed to give a total weight of 2380 g and the following atomic ratio.

Atomic ratio: (Fe₄₀—Pt₄₅—Cu₁₅)₅₅—C₄₅

Next, the weighed powders were transferred and sealed in a 10 L ball mill pot along with zirconia balls as grinding media, and rotated for 4 hours for mixing and grinding. Then the mixed powder was removed from the ball mill to perform heat treatment.

The conditions of the heat treatment were as follows: Ar atmosphere (atmospheric pressure), the rate of temperature increase: 300° C./hour, holding temperature: 800° C. and holding time: 2 hours. The powder was removed from the heat treating furnace after naturally cooled, and transferred and sealed in a 10 L ball mill pot along with zirconia balls as grinding media, and rotated for 4 hours for crushing and grinding.

The carbon mold was then filled with the crushed and ground powder for hot pressing.

The conditions of the hot pressing were as follows: vacuum atmosphere, the rate of temperature increase: 300° C./hour, holding temperature: 1200° C. and holding time: 2 hours, and pressure was applied at 30 MPa from the beginning of temperature increase through to the end of holding. After holding, it was kept in the chamber to allow natural cooling.

Next, the sintered compact removed from the mold for the hot pressing was subjected to hot isostatic pressing. The conditions of the hot isostatic pressing were as follows: the rate of temperature increase: 300° C./hour, holding temperature: 1350° C. and holding time: 2 hours, and the gas pressure of Ar gas was gradually increased from the beginning of temperature increase and pressure was applied at 150 MPa during holding at 1350° C. After holding, it was kept in the furnace to allow natural cooling.

The sintered compact manufactured in this way was subject to cutting work with a lathe to obtain a sputtering target. At the same time, a sample for oxygen analysis was cut out from the sintered compact, and the oxygen content was measured to be 210 wt ppm. Further, the sintered compact was polished to observe the cross section, and a structure was observed in which C particles are finely dispersed in the Fe—Pt—Cu alloy.

### Comparative Example 2

An Fe powder having an average particle diameter of 3 μm, a Pt powder having an average particle diameter of 3 μm, a Cu powder having an average particle diameter of 3 μm and a C powder having an average particle diameter of 1 μm were prepared as raw powders. For the C powder, a commercially available amorphous carbon was used.

These powders were weighed to give a total weight of 2380 g and the following atomic ratio.

Atomic ratio: (Fe₄₀—Pt₄₅—Cu₁₅)₅₅—C₄₅

Next, the weighed powders were transferred and sealed in a 10 L ball mill pot along with zirconia balls as grinding media, and rotated for 4 hours for mixing and grinding. A carbon mold was then filled with the mixed powder removed from the ball mill for hot pressing.

The conditions of the hot pressing were as follows: vacuum atmosphere, the rate of temperature increase: 300° C./hour, holding temperature: 1200° C. and holding time: 2 hours, and pressure was applied at 30 MPa from the beginning of temperature increase through to the end of holding. After holding, it was kept in the chamber to allow natural cooling.

Next, the sintered compact removed from the mold for the hot pressing was subjected to hot isostatic pressing. The conditions of the hot isostatic pressing were as follows: the rate of temperature increase: 300° C./hour, holding temperature: 1350° C. and holding time: 2 hours, and the gas pressure of Ar gas was gradually increased from the beginning of temperature increase and pressure was applied at 150 MPa during holding at 1350° C. After holding, it was kept in the furnace to allow natural cooling.

The sintered compact manufactured in this way was subject to cutting work with a lathe to obtain a sputtering target. At the same time, a sample for oxygen analysis was cut out from the sintered compact, and the oxygen content was measured to be 540 wt ppm. Further, the sintered compact was polished to observe the cross section, and a structure was observed in which C particles are finely dispersed in the Fe—Pt—Cu alloy.

### Example 3

An Fe powder having an average particle diameter of 3 μm, a Pt powder having an average particle diameter of 3 μm, an Ag powder having an average particle diameter of 1 μm and a C powder having an average particle diameter of 1 μm were prepared as raw powders. For the C powder, a commercially available amorphous carbon was used.

These powders were weighed to give a total weight of 2200 g and the following atomic ratio.

Atomic ratio: (Fe_{42.5}—Pt_{42.5}—Ag₁₅)₆₀—C₄₀

Next, the weighed powders were transferred and sealed in a 10 L ball mill pot along with zirconia balls as grinding media, and rotated for 4 hours for mixing and grinding. Then the mixed powder was removed from the ball mill to perform heat treatment.

The conditions of the heat treatment were as follows: Ar atmosphere (atmospheric pressure), the rate of temperature increase: 300° C./hour, holding temperature: 850° C. and holding time: 2 hours. The powder was removed from the heat treating furnace after naturally cooled, and transferred and sealed in a 10 L ball mill pot along with zirconia balls as grinding media, and rotated for 4 hours for crushing and grinding.

The carbon mold was then filled with the crushed and ground powder for hot pressing.

The conditions of the hot pressing were as follows: vacuum atmosphere, the rate of temperature increase: 300° C./hour, holding temperature: 900° C. and holding time: 2 hours, and pressure was applied at 30 MPa from the beginning of temperature increase through to the end of holding. After holding, it was kept in the chamber to allow natural cooling.

Next, the sintered compact removed from the mold for the hot pressing was subjected to hot isostatic pressing. The conditions of the hot isostatic pressing were as follows: the rate of temperature increase: 300° C./hour, holding temperature: 900° C. and holding time: 2 hours, and the gas pressure of Ar gas was gradually increased from the beginning of temperature increase and pressure was applied at 150 MPa during holding at 900° C. After holding, it was kept in the furnace to allow natural cooling.

The sintered compact manufactured in this way was subject to cutting work with a lathe to obtain a sputtering target. At the same time, a sample for oxygen analysis was cut out from the sintered compact, and the oxygen content was measured to be 270 wt ppm. Further, the sintered compact was polished to observe the cross section, and a structure was observed in which C particles are finely dispersed in the alloy having 2 phases of Fe—Pt and Ag.

### Comparative Example 3

An Fe powder having an average particle diameter of 3 μm, a Pt powder having an average particle diameter of 3 μm, an Ag powder having an average particle diameter of 1 μm and a C powder having an average particle diameter of 1 μm were prepared as raw powders. For the C powder, a commercially available amorphous carbon was used.

The powders were weighed to give a total weight of 2200 g and the following atomic ratio.

Atomic ratio: (Fe_{42.5}—Pt_{42.5}—Ag₁₅)₆₀—C₄₀

Next, the weighed powders were transferred and sealed in a 10 L ball mill pot along with zirconia balls as grinding media, and rotated for 4 hours for mixing and grinding. A carbon mold was then filled with the mixed powder removed from the ball mill for hot pressing.

The conditions of the hot pressing were as follows: vacuum atmosphere, the rate of temperature increase: 300° C./hour, holding temperature: 900° C. and holding time: 2 hours, and pressure was applied at 30 MPa from the beginning of temperature increase through to the end of holding. After holding, it was kept in the chamber to allow natural cooling.

Next, the sintered compact removed from the mold for the hot pressing was subjected to hot isostatic pressing. The conditions of the hot isostatic pressing were as follows: the rate of temperature increase: 300° C./hour, holding temperature: 900° C. and holding time: 2 hours, and the gas pressure of Ar gas was gradually increased from the beginning of temperature increase and pressure was applied at 150 MPa during holding at 900° C. After holding, it was kept in the furnace to allow natural cooling.

The sintered compact manufactured in this way was subject to cutting work with a lathe to obtain a sputtering target. At the same time, a sample for oxygen analysis was cut out from the sintered compact, and the oxygen content was measured to be 810 wt ppm. Further, the sintered compact was polished to observe the cross section, and a structure was observed in which C particles are finely dispersed in the alloy having 2 phases of Fe—Pt and Ag.

As described above, the results showed that the sputtering targets of the present invention in all Examples had an oxygen content of 300 wt ppm or less and a structure in which C particles were finely dispersed.

### INDUSTRIAL APPLICABILITY

The present invention has the following advantageous effect: it can provide an Fe—Pt—C based sputtering target having finely dispersed C particles and an oxygen content of 300 wt ppm or less, which allows manufacture of a granular structure magnetic thin film and further allows facilitation of ordering the L1₀ structure. Hence, the present invention is useful for manufacturing a magnetic recording medium comprising a granular structure magnetic film.

1. A sputtering target having a composition by atomic ratio represented by the formula: (Fe_{100-X}—Pt_{X})_{100-A}C_{A} (wherein A and X satisfy 20≦A≦50 and 35≦X≦55, respectively), wherein C particles are finely dispersed in a matrix alloy, and an oxygen content is 300 wt ppm or less.

2. A sputtering target having a composition by atomic ratio represented by the formula: (Fe_{100-X}—Pt_{X})_{100-A}C_{A} (wherein M is a metal element other than Fe and Pt, and A, X and Y satisfy 20≦A≦50, 35≦X≦55 and 0.5≦Y≦15, respectively), wherein C particles are finely dispersed in a matrix alloy, and an oxygen content is 300 wt ppm or less.

3. The sputtering target according to claim 2, wherein the metal element M is either Cu or Ag.

4. A method of manufacturing an Fe—Pt—C based sputtering target, the method comprising: mixing metal powders of an Fe powder, a Pt powder and a C powder; heat-treating the mixed powder at temperature of 750° C. or more and 1100° C. or less under an inert gas atmosphere or a vacuum atmosphere; preparing the resulting powder as a part of a raw powder; further adjusting the raw powder to give a composition by atomic ratio represented by the formula: (Fe_{100-X}—Pt_{X})_{100-A}C_{A}, wherein A and X satisfy 20≦A≦50 and 35≦X≦55, respectively; and then performing sintering.

5. The method of manufacturing a sputtering target according to claim 4, the method comprising: filling a mold with the heat-treated powder; performing molding and sintering by uniaxial pressing at a pressure of 20 to 50 MPa; and further performing molding and sintering by hot isostatic pressing at a pressure of 100 to 200 MPa.

6. A method of manufacturing an Fe—Pt—C based sputtering target, the method comprising: mixing an Fe powder, a Pt powder and a metal powder of M and a C powder; heat-treating the mixed powder at temperature of 750° C. or more and 1100° C. or less under an inert gas atmosphere or a vacuum atmosphere; preparing the resulting powder as a part of a raw powder; further adjusting the raw powder to give a composition by atomic ratio represented by the formula: (Fe_{100-X-Y}—Pt_{X}—M_{Y})_{100-A}C_{A}, wherein M is a metal element other than Fe and Pt, and A, X and Y satisfy 20≦A≦50, 35≦X≦55 and 0.5≦Y≦15, respectively; and then performing sintering.

7. The method according to claim 6, wherein the metal element M is selected from the group consisting of Cu and Ag.

8. The method according to claim 7, wherein, after said steps of mixing, heat-treating, preparing and adjusting, said sintering step includes the steps of: filling a mold with the powder; performing molding and sintering by uniaxial pressing at a pressure of 20 to 50 MPa; and further performing molding and sintering by hot isostatic pressing at a pressure of 100 to 200 MPa.

9. The method according to claim 6, wherein, after said steps of mixing, heat-treating, preparing and adjusting, said sintering step includes the steps of: filling a mold with the powder; performing molding and sintering by uniaxial pressing at a pressure of 20 to 50 MPa; and further performing molding and sintering by hot isostatic pressing at a pressure of 100 to 200 MPa.
